(19) United States
(12) Patent Application Publication
(10) Pub. No.: US 2010/0323466 A1
(43) Pub. Date: Dec. 23, 2010

(54) LIGHT EMITTING DIODE LAMP WITH PHOSPHOR COATED RELECTOR

(75) Inventors: Rene HELBING, Livermore, CA (US); Jianhua Li, Livermore, CA (US)

Correspondence Address: Arent Fox LLP, 555 West Fifth Street, 48th Floor, Los Angeles, CA, 90013, US

(73) Assignee: Bridgelux, Inc., Livermore, CA (US)

(21) Appl. No.: 12/862,939

(22) Filed: Aug. 25, 2010

Related U.S. Application Data
(62) Division of application No. 12/365,092, filed on Feb. 3, 2009.

(51) Int. Cl. H01L 33/60; H01L 33/48

(52) U.S. Cl. 438/27; 438/28; 257/E33.056; 257/E33.061; 257/E33.067

(57) ABSTRACT

A light emitting apparatus includes a lamp reflector having phosphor, wherein the lamp reflector further includes an aperture, and an LED light source arranged with the lamp reflector to excite the phosphor and to emit light through the aperture of the lamp reflector.

### CROSS-REFERENCE TO RELATED APPLICATION(S)

This is a Divisional Application which claims the benefit of pending U.S. patent application Ser. No. 12/365,092, filed on Feb. 3, 2009. The disclosure of the prior application is hereby incorporated herein in its entirety by reference.

### BACKGROUND

1. Field

The present disclosure relates to light emitting devices, and more particularly to light emitting diode lamps with phosphor coated reflectors.

2. Background

A white LED lamp is generally constructed with a white Light Emitting Diode (LED). The white LED is generally mounted to a heat sink and surrounded by a lamp reflector. A diffuser is commonly positioned at the output aperture of the reflector.

A white LED can be produced by applying a layer of phosphor to a blue LED. A portion of the blue light from the LED is absorbed by the phosphor and the remaining blue light passes through the phosphor. Once the blue light is absorbed by the phosphor, the phosphor emits yellow light. This secondary emission of yellow light from the phosphor, also known as a Stokes shift, is optically mixed with the remaining blue light, and the mixed spectra thus produced is perceived by the human eye as being white.

A number of technical issues currently exist with a white LED constructed in this fashion. The blue LED itself tends to generate a significant amount of heat. When the blue light strikes the phosphor, additional heat is generated due to stokes shift and quantum efficiency loss. The heat build up in the white LED in turn degrades the performance of the blue LED and the phosphor, causing light output drop, color temperature shift, and shorter lifetime.

Accordingly, there is a need in the art for improved heat dissipation in a white LED constructed from a phosphor coated blue LED. Preferably, these improvements should extend to other color LED and phosphor combinations that produce different color lights.

### SUMMARY

In one aspect of the disclosure, a light emitting apparatus includes a lamp reflector having phosphor, wherein the lamp reflector further includes an aperture, and an LED light source arranged with the lamp reflector to excite the phosphor and to emit light through the aperture of the lamp reflector.

In another aspect of the disclosure, a light emitting apparatus includes a substrate, an LED light source on the substrate, and a lamp reflector on the substrate surrounding the LED light source, wherein the lamp reflector comprises an inner surface having phosphor and aperture aligned with the LED light source.

In yet another aspect of the disclosure, a light emitting apparatus includes means for emitting light having a first wavelength, and a lamp reflector having means for converting a portion of the light to a second wavelength and an aperture aligned with the light emitting means.

In a further aspect of the disclosure, a method of fabricating a light emitting apparatus having a lamp reflector and an aperture includes applying phosphor to an inner surface of the lamp reflector, and arranging an LED light source with the lamp reflector to excite the phosphor and emit light through the aperture.

It is understood that other aspects of the present invention will become readily apparent to those skilled in the art from the following detailed description, wherein it is shown and described only exemplary configurations of an LED lamp by way of illustration. As will be realized, the present invention includes other and different aspects of an LED lamp and its several details are capable of modification in various other respects, all without departing from the spirit and scope of the present invention. Accordingly, the drawings and the detailed description are to be regarded as illustrative in nature and not as restrictive.

### BRIEF DESCRIPTION OF THE FIGURES

Various aspects of the present invention are illustrated by way of example, and not by way of limitation, in the accompanying drawings, wherein:

FIG. 1 is a conceptual cross-sectional view illustrating an example of an LED;

FIG. 2A is a conceptual top view illustrating an example of an LED array;

FIG. 2B is a conceptual cross-sectional view of the LED array of FIG. 2A;

FIG. 3A is a conceptual top view illustrating an example of an encapsulated LED array;

FIG. 3B is a conceptual cross-sectional view of the encapsulated LED array of FIG. 3A;

FIG. 4 is a conceptual cross-sectional view of an LED lamp; and

FIG. 5 is a conceptual cross-sectional view of another configuration of an LED lamp.

### DETAILED DESCRIPTION

The present invention is described more fully hereinafter with reference to the accompanying drawings, in which various aspects of the present invention are shown. This invention, however, may be embodied in many different forms and should not be construed as limited to the various aspects of the present invention presented throughout this disclosure. Rather, these aspects are provided so that this disclosure will be thorough and complete, and will fully convey the scope of the present invention to those skilled in the art. The various aspects of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method.

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, bulb shapes, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower”, can therefore, encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of an LED lamp will now be presented. However, as those skilled in the art will readily appreciate, these aspects may be extended to other light sources without departing from the invention. The LED lamp may include a light source comprising one or more LEDs and a lamp reflector coated with phosphor. The LED is well known in the art, and therefore, will only briefly be discussed to provide a complete description of the invention.

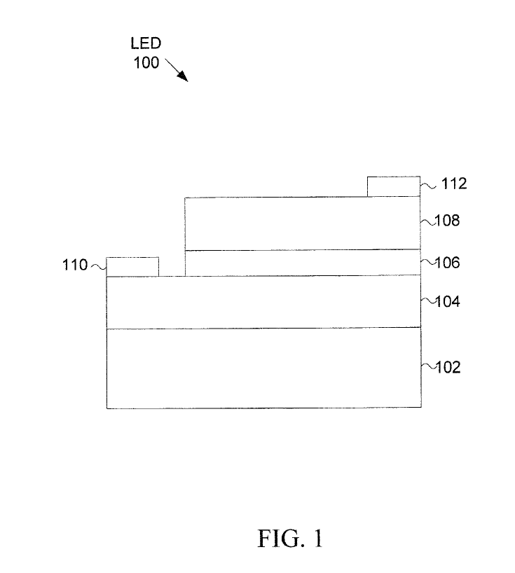

FIG. 1 is a conceptual cross-sectional view illustrating an example of an LED. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes, and is referred respectively as N-type or P-type semiconductor regions. Referring to FIG. 1, the LED 100 includes a substrate 102 supporting an N-type semiconductor region 104 and a P-type semiconductor region 108. A reverse electric field is created at the junction between the two regions, which cause the electrons and holes to move away from the junction to form an active region 106. When a forward voltage sufficient to overcome the reverse electric field is applied across the PN junction through a pair of electrodes 110, 112, electrons and holes are forced into the active region 106 and recombine. When electrons recombine with holes, they fall to lower energy levels and release energy in the form of light.

The N-type semiconductor region 104 is formed on a substrate 102 and the P-type semiconductor region 108 is formed on the active layer 106, however, the regions may be reversed. That is, the P-type semiconductor region 108 may be formed on the substrate 102 and the N-type semiconductor region 104 may formed on the active layer 106. As those skilled in the art will readily appreciate, the various concepts described throughout this disclosure may be extended to any suitable layered structure. Additional layers or regions (not shown) may also be included in the LED 100, including but not limited to buffer, nucleation, contact and current spreading layers or regions, as well as light extraction layers.

The P-type semiconductor region 108 is exposed at the top surface, and therefore, the P-type electrode 112 may be readily formed thereon. However, the N-type semiconductor region 104 is buried beneath the P-type semiconductor layer 108 and the active layer 106. Accordingly, to form the N-type electrode 110 on the N-type semiconductor region 104, a cutout area or “mesa” is formed by removing a portion of the active layer 106 and the P-type semiconductor region 108 by means well known in the art to expose the N-type semiconductor layer 104 therebeneath. After this portion is removed, the N-type electrode 110 may be formed.

In one example of an LED, the wavelength of light is in the blue region of the electromagnetic spectrum. However, as indicated earlier, the various inventive concepts are not limited to a blue LED and may be extended to other LED colors and/or light sources. A blue LED may be constructed from a wide band gap semiconductor material such as gallium nitride (GaN), indium gallium nitride (InGaN), or some other suitable material. In one example of a blue LED, the PN junction has an active layer comprising of one or more InGaN quantum wells sandwiched between thicker layers of GaN, called cladding layers.

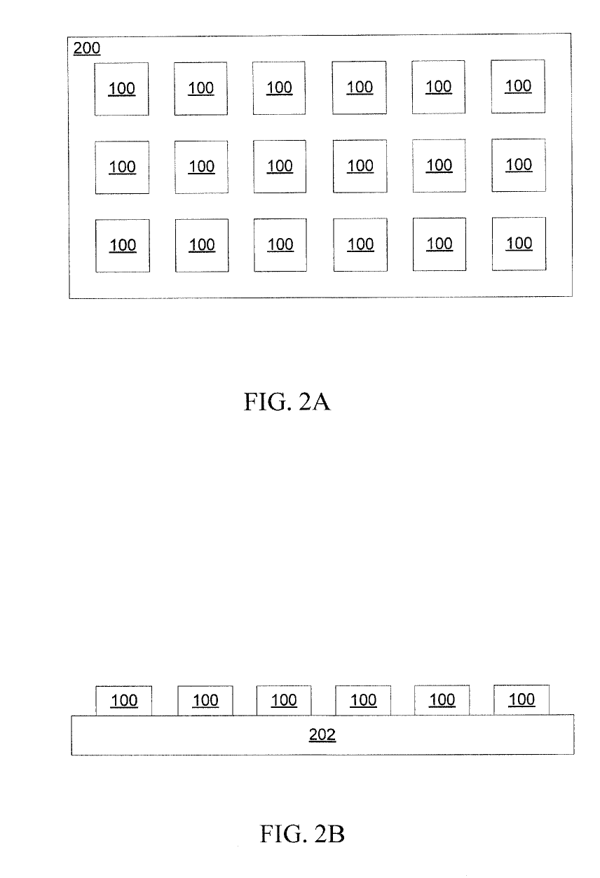

In a configuration of an LED lamp, an array of LEDs may be used to provide increased light output. FIG. 2A is a conceptual top view illustrating an example of an LED array 200, and FIG. 2B is a conceptual cross-sectional view of the LED array 200 of FIG. 2A. In this example, a number of LEDs 100 may be formed on a substrate 202 by means well known in the art. The LEDs may be constructed to emit blue light or some other color. The bond wires (not shown) extending from the LEDs 100 may be connected to traces (not shown) on the surface of the substrate 202, which connect the LEDs 100 in a parallel and/or series fashion. Typically, the LEDs 100 may be connected in parallel streams of series LEDs, driven by constant current power source. The substrate 102 may be any suitable material that can provide support to the LEDs 100 and can be mounted within a lamp reflector (not shown).

Optionally, the LED array 200 may be encapsulated in an epoxy, silicone, or other thermally-conductive transparent encapsulation material. The encapsulation material may be used to focus the light emitted from the LEDs 100, as well as protect the wire bonding on the LEDs 100. By encapsulating the LEDs 100, the LED array 200 becomes extremely durable with no loose or moving parts. As a result, the LED array 200 becomes essentially an array of PN junction semiconductor diodes that emit light when a forward voltage is applied, resulting in a very reliable device.

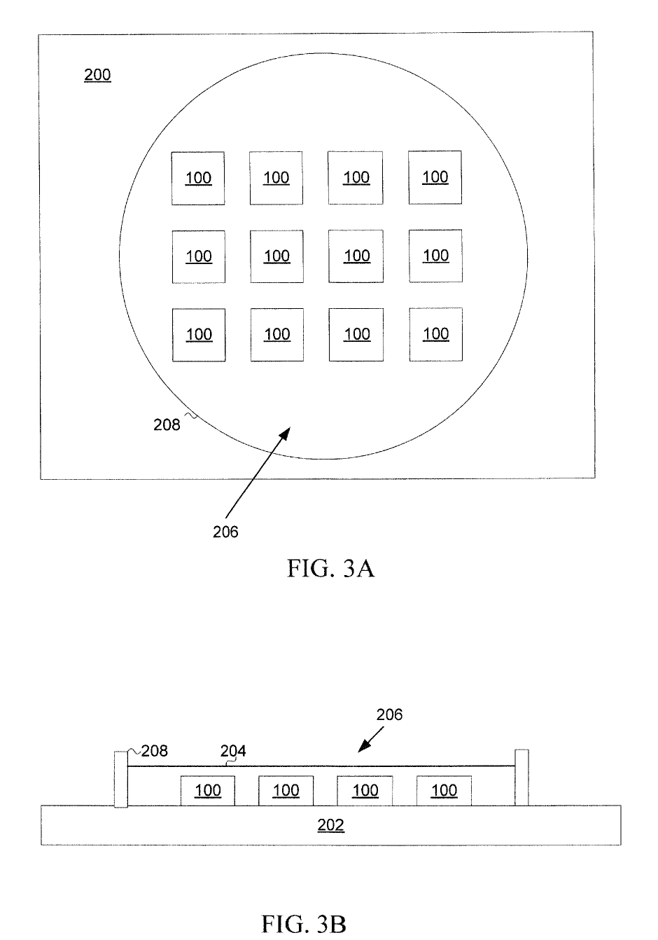

Turning to FIGS. 3A and 3B, encapsulation material 204 may be deposited within a cavity 206 bounded by a ring 208 that extends circumferentially around the outer surface of the substrate 202. The ring 208 may be circular, rectangular, or some other suitable shape. The ring 208 may be formed separately from the substrate 202 and attached to the substrate using adhesive or other means. Alternatively, the substrate 202 and the ring 208 may be formed with a suitable mold or the ring 208 may be formed by boring a cylindrical hole in a material that forms the substrate 202.

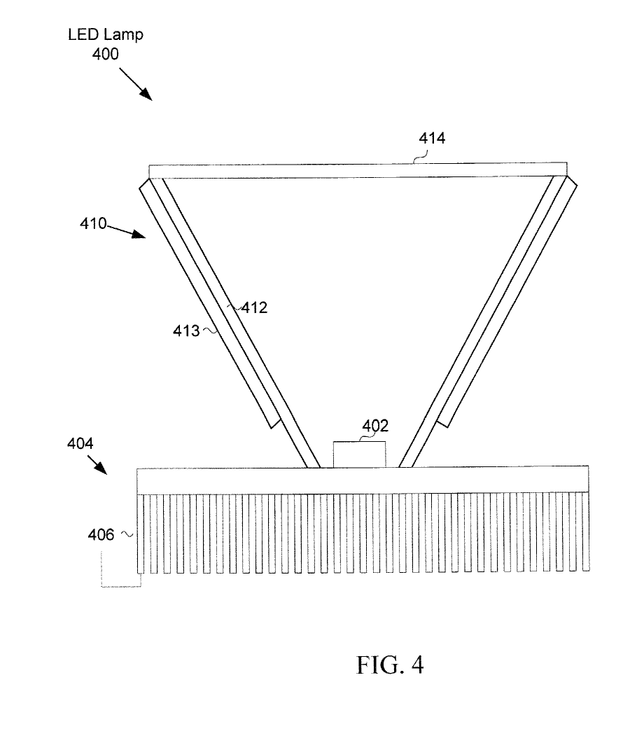

FIG. 4 is a conceptual cross-sectional view of an LED lamp. The LED lamp 400 may include an LED light source 402 comprising an LED array. The LED array may take on various forms, including any one of the configurations discussed earlier, or any other suitable configuration now known or which later comes to be known. In one configuration of an LED lamp 400, the LED light source 402 may be formed with a number of blue LEDs, however, other configurations of the LED light source 402 may be formed with any number of different color LEDs or any combination of LED colors. Although an LED array is well suited for an LED lamp, those skilled in the art will readily understand that the various concepts presented throughout this disclosure are not necessarily limited to array of LEDs and may be extended to a light source comprising a single LED.

The LED light source 402 may be mounted to a substrate 404. The substrate 404 may be a heat sink configured to dissipate the heat generated by the LED light source 402 by transferring it to the surrounding air. In this example, the heat sink is in thermal contact with the LED light source 402 and includes an array of fins 406 to increase the heat sink's surface area contacting the air, thus increasing the heat dissipation rate. The heat sink is preferably a good thermal conductor, such as copper or aluminum alloy. Optionally, a fan (not shown) may be used to provide increased airflow over the heat sink.

A lamp reflector 410 with a phosphor coating 412 may be positioned on the substrate 404 surrounding the LED light source 402. The lamp reflector 410 provides a means for controlling the beam shape of the light emitted from the LED light source 402. The lamp reflector 410 may be made out of a heat conductive material, such as metal or other suitable material, to transfer the heat generated by the phosphor to the substrate 404. The lamp reflector 410 may also include fins 413 to better dissipate the heat, but alternative configurations of the lamp reflector 410 may be constructed without fins. The fins 413 may be oriented vertically as shown, or in any other suitable direction (e.g., horizontal). The lamp reflector 410 is shown with a conical shape, but may take on other shapes depending on the particular application.

As described earlier, the phosphor 412 applied to the lamp reflector 410 absorbs high energy light emitted by the LED light source 402 and emits low energy light having a different wavelength. A white LED light source can be constructed by using an LED array that emits blue light. A portion of the blue light from the LED light source 402 is absorbed by the phosphor 412 and the remaining blue light passes through the phosphor 412. Once the blue light is absorbed by the phosphor 412, the phosphor 412 emits yellow light. The yellow light from the phosphor 412 is optically mixed with the remaining blue light to produce a mixed spectra that is perceived by the human eye as being white. A white LED light source is well suited as an LED lamp for most applications; however, the invention may be practiced with other LED and phosphor combinations to produce different color lights.

By applying the phosphor 412 to the lamp reflector 410, the heat generated in the LED light source 402 is reduced, and as a result, the LED light source 402 outputs more light with improved reliability and longer lifetime. In addition, the heat generated by the phosphor 412 is widely distributed over the lamp reflector 410, and therefore, the phosphor 412 will experience less degradation, less color shift, better stability, and more efficient light converting as described in the previous paragraph. Finally, the light resulting from phosphor scattering that would otherwise be absorbed by the LED light source 402 if it were completely encapsulated by the phosphor is no longer an issue, resulting in increased light output. Optionally, the area on the substrate 404 between the LED light source 402 and the lamp reflector 410 may also be coated with phosphor.

In one example of an LED lamp 400, the lamp reflector 410 may be detachable from the substrate 404. With different formulas for phosphor, the LED lamp 400 may be configured to generate cool, neutral, or warm white light. During the long lifetime of the LED light source, the customer may grow tired of the LED lamp color. A detachable lamp reflector 410 would enable the customer to change the color by simply replacing the reflector 410. The detachable light reflector 410 may also reduce manufacturing costs. The LED light source 402, the substrate 404, and the driver circuitry (not shown) for the LED light source 402 may be manufactured as a standard box, while the lamp reflector 410 may be an option for customers/users.

The lamp reflector 410 may have at its output aperture a transparent optical element 414. The optical element 414 may be a diffuser configured to scatter light to make the light appear more uniform to an observer. The optical element 414 may be snap fit, adhered, or attached by some other means to the lamp reflector 410.

The LED lamp 400 may include a driver circuit (not shown) and an AC-DC converter (not shown). The AC-DC converter may be used to generate a DC voltage from an AC power source generally found in a household, office building, or other facility. The DC voltage generated by the AC-DC converter may be provided to the driver circuit configured to drive the LED light source 402. The AC-DC converter and the driver circuit may be located on the substrate 404, outside the lamp reflector 410, or anywhere else in the LED lamp 400. In some applications, the AC-DC converter may not be needed. By way of example, the LED light source 402 may be designed for AC power. Alternatively, the power source may be DC, such as the case might be in automotive applications. The particular design of the power delivery circuit for any particular application is well within the capabilities of one skilled in the art.

Various examples of a process for applying phosphor to a lamp reflector will now be presented. However, as those skilled in the art will readily appreciate, the inventive concepts described throughout this disclosure are not limited to such processes.

In one example, phosphor powder may be applied to the inner surface of the lamp reflector 410. A binder may be mixed with the phosphor powder, or alternatively, the binder may be applied directly to the inner surface of the lamp reflector 410. Once the phosphor powder is applied, the lamp reflector 410 may be heated in a furnace to further bind the phosphor to the lamp reflector 410 and to drive out any impurities in the phosphor. The lamp reflector 410 may then be cooled and hardened.

Another example of a process for applying phosphor to a lamp reflector involves electro-deposition. In this example, the phosphor is deposited onto a plate. The plate and the lamp reflector are then connected to a DC power supply or battery with the plate being connected to the positive terminal and the lamp reflector being connected to the negative terminal. Both the plate and reflector may be immersed in an electrolyte solution. When power is applied, the metal molecules in the phosphor oxidize and are dissolved in the solution. At the lamp reflector, the metal molecules dissolved in the electrolyte solution are reduced at the interface between the solution and the lamp reflector such that they plate out onto the reflector. This process may be repeated as many times as necessary to achieve the desired amount of phosphor.

A further example of a process for applying phosphor to a lamp reflector involves vapor deposition. In this example, a thin film of phosphor is deposited on the lamp reflector by the condensation of vaporized phosphor onto the inner surface of the reflector. More specifically, the process is performed by vaporizing the phosphor and then filling the lamp reflector with the vaporized gas. The gas is then cooled resulting in a layer of solidified phosphor on the inner surface of the lamp reflector. This process may be repeated as many times as necessary to achieve the desired amount of phosphor.

The various methods presented thus far for applying phosphor to a lamp reflector are non-limiting examples intended to enable those skilled in the art to practice the full scope of the invention. It will be understood that other methods for applying phosphor to a lamp reflector may be used without departing from the spirit and scope of the invention. By way of example, a brush or other apparatus may be used to apply a phosphor paste to the lamp reflector. Alternatively, a pre-prepared thin-film phosphor tape may be applied to the lamp reflector or a pre-manufactured, free-standing phosphor film may be mounted to the lamp reflector with adhesive. The various concepts presented throughout this disclosure are intended to apply to any suitable method for applying phosphor to a lamp reflector now known or which later comes to be known.

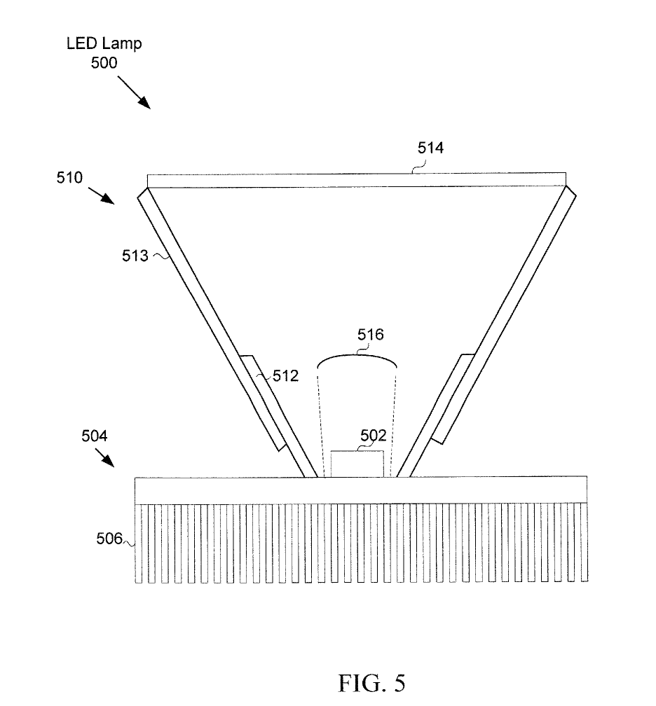

FIG. 5 is a conceptual cross-sectional view of an alternative configuration of an LED lamp. In this example, the LED lamp 500 is similar to that presented earlier in connection with FIG. 4. The LED lamp 500 includes an LED light source 502 with any associated electronics (not shown) to power and drive the source 502. The LED light source 502 is mounted to a substrate 504 and a lamp reflector 510 is positioned on the substrate 504 surrounding the LED light source 502. In this configuration, both the substrate 504 and the lamp reflector 510 include fins 506, 513, respectively, but such fins are not required. The lamp reflector 510 includes at its output aperture a transparent optical element 514. The principle difference in this configuration is the inclusion of a second reflector 516.

The second reflector 516 is positioned in front of the LED light source 502. The second reflector 516 blocks a direct view of the LED light source 502, reflecting a portion of the emitted light towards the lamp reflector 510, the substrate 504, and the LED light source 502. Most of the emitted light reflected by the second reflector 516 will be reflected back by the lamp reflector 510 to the optical element 514 creating a more uniform light. A reflective coating may be applied to the substrate 504 between the LED light source 502 and the lamp reflector 510. The lamp reflector 510 may be partially coated with phosphor 512 to save cost, provided the coated surface is sufficient to dissipate the heat.

The various aspects of this disclosure are provided to enable one of ordinary skill in the art to practice the present invention. Various modifications to aspects presented throughout this disclosure will be readily apparent to those skilled in the art, and the concepts disclosed herein may be extended to other LED lamp configurations regardless of the shape, application, or design constraints. Thus, the claims are not intended to be limited to the various aspects of this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A method of fabricating a light emitting apparatus having a lamp reflector with an aperture, comprising:
applying phosphor to an inner surface of the lamp reflector; and
arranging an LED light source with the lamp reflector to excite the phosphor and emit light through the aperture.

2. The method of claim 1 wherein the LED light source comprises an array of LEDs.

3. The method of claim 1 wherein the LED light source comprises at least on blue LED.

4. The method of claim 1 further comprising positioning the LED light source and the lamp reflector on a substrate such that the lamp reflector surrounds the LED light source.

5. The method of claim 4 wherein the substrate comprises a heat sink.

6. The method of claim 4 further comprising detachably connecting the lamp reflector to the substrate.

7. The method of claim 1 further comprising positioning arranging a transparent optical element at the aperture of the lamp reflector.

8. The method of claim 1 further comprising positioning a second reflector between the LED light source and the aperture of the lamp reflector.

9. The method of claim 8 wherein the phosphor is applied to only a portion of the inner surface of the lamp reflector and the second reflector is positioned such that a portion of light emitted by the LED light source is reflected towards at least the portion of the inner surface of the lamp reflector with the phosphor.
